(19) United States
(12) Patent Application Publication
(10) Pub. No.: US 2026/0331869 A1
(43) Pub. Date: Oct. 22, 2026

(54) METHOD AND APPARATUS FOR MEASURING LASER LINEWIDTH BASED ON DIGITAL DECOHERENCE

(71) Applicant: TSINGHUA UNIVERSITY, Beijing (CN)

(72) Inventors: Bo WANG, Beijing (CN); Zhongwang PANG, Beijing (CN)

(73) Assignee: TSINGHUA UNIVERSITY, Beijing (CN)

(21) Appl. No.: 19/538,578

(22) Filed: Feb. 12, 2026

(30) Foreign Application Priority Data
Apr. 16, 2025 (CN) 202510478148.4

(51) Int. Cl. H01S 5/0687

(52) U.S. Cl. CPC H01S 5/0687

(57) ABSTRACT

A method and an apparatus for measuring a laser linewidth based on digital decoherence are provided, which are applicable to the technical field of laser linewidth measurement. The method includes: acquiring a first delayed beam and a first reference beam from a laser under test; performing digital decoherence at least based on the first delayed beam and the first reference beam to determine a frequency noise power spectral density of the laser under test; and determining the laser linewidth of the laser under test based on the frequency noise power spectral density.

### CROSS REFERENCE TO RELATED APPLICATION

The present application claims priority to Chinese Patent Application No. 202510478148.4 filed on Apr. 16, 2025, which application is incorporated herein by reference in its entirety.

### TECHNICAL FIELD

The present disclosure relates to the technical field of laser linewidth measurement, and in particular to a method and an apparatus for measuring a laser linewidth based on digital decoherence.

### BACKGROUND

The phase noise and linewidth of a laser are key parameters for evaluating the frequency stability and phase noise characteristics of the laser, which are of great importance in fields such as high-precision laser measurement, optical communication, and quantum technology. Conventional methods for measuring the phase noise and linewidth of the laser primarily include a heterodyne beat method and a delayed self-heterodyne method.

When measuring the laser by using the heterodyne beat method, one or more additional reference laser is required, and a center wavelength of the reference laser is required to be sufficiently close to that of a laser under test, resulting in limited flexibility and applicability in measuring a laser linewidth by using the heterodyne beat method.

When measuring the laser by using the delayed self-heterodyne method, a fiber delay line introduces substantial environmental noise, thereby compromising the measurement accuracy of the laser linewidth.

### SUMMARY

In view of this, a method and an apparatus for measuring a laser linewidth based on digital decoherence are provided according to embodiments of the present disclosure, to address issues of limited flexibility, limited applicability, and low measurement accuracy existing in conventional methods for measuring the laser linewidth.

To achieve the above objectives, technical solutions are provided according to embodiments of the present disclosure as follows.

According to a first aspect of the present disclosure, a method for measuring a laser linewidth based on digital decoherence is provided. The method includes: acquiring a first delayed beam and a first reference beam from a laser under test; performing digital decoherence at least based on the first delayed beam and the first reference beam to determine a frequency noise power spectral density of the laser under test; and determining the laser linewidth of the laser under test based on the frequency noise power spectral density.

In an embodiment, the performing digital decoherence at least based on the first delayed beam and the first reference beam to determine a frequency noise power spectral density of the laser under test includes: acquiring a second delayed beam and a second reference beam from an auxiliary laser; performing demodulation by using the first delayed beam, the first reference beam, the second delayed beam, and the second reference beam to obtain first phase difference data of the laser under test and second phase difference data of the auxiliary laser; suppressing noise induced by a fiber delay line by using the first phase difference data and the second phase difference data to obtain third phase difference data; performing digital decoherence on the first phase difference data to obtain fourth phase difference data, and performing digital decoherence on the third phase difference data to obtain fifth phase difference data; and determining the frequency noise power spectral density of the laser under test by using the fourth phase difference data and the fifth phase difference data.

In an embodiment, the performing digital decoherence at least based on the first delay beam and the first reference beam to determine a frequency noise power spectral density of the laser under test includes: performing demodulation by using the first delay beam and the first reference beam to obtain first phase difference data of the laser under test; performing digital decoherence on the first phase difference data to obtain fourth phase difference data; and determining the frequency noise power spectral density of the laser under test based on the fourth phase difference data.

In an embodiment, the performing demodulation by using the first delayed beam, the first reference beam, the second delayed beam, and the second reference beam to obtain first phase difference data of the laser under test and second phase difference data of the auxiliary laser includes: combining the first delayed beam and the second delayed beam, transmitting a combination of the first delayed beam and the second delayed beam to a fiber delay line to obtain a delayed beam, and performing frequency shifting on the delayed beam to obtain a third delayed beam; combining the third delayed beam and the first reference beam, performing an interference measurement on a combination of the third delayed beam and the first reference beam to obtain a first interference signal, combining the third delayed beam and the second reference beam, and performing an interference measurement on a combination of the third delayed beam and the second reference beam to obtain a second interference signal; and demodulating the first interference signal to obtain the first phase difference data, and demodulating the second interference signal to obtain the second phase difference data.

In an embodiment, the performing demodulation by using the first delayed beam and the first reference beam to obtain first phase difference data of the laser under test includes: transmitting the first delayed beam to the fiber delay line to obtain a delayed beam, and performing frequency shifting on the delayed beam to obtain a fourth delayed beam; combining the fourth delayed beam and the first reference beam, and performing an interference measurement on a combination of the fourth delayed beam and the first reference beam by using a photodetector to obtain a third interference signal; and demodulating the third interference signal to obtain the first phase difference data.

In an embodiment, the performing digital decoherence on the first phase difference data to obtain fourth phase difference data includes: delaying the first phase difference data by a specified delay to form new phase difference data; comparing the new phase difference data with the first phase difference data to obtain output phase difference data with two specified delays; delaying the new phase difference data by the specified delay to update the new phase difference data; comparing the updated new phase difference data with output phase difference data with (i−1) specified delays to obtain output phase difference data with i specified delays, where i is 3; and performing multiple operations until i is greater than m to obtain the fourth phase difference data, where each operation of the multiple operations includes: increasing i by 1, delaying the new phase difference data by the specified delay to update the new phase difference data, and comparing the updated new phase difference data with output phase difference data with (i−1) specified delays to obtain output phase difference data with i specified delays, and the fourth phase difference data is output phase difference data with m specified delays.

In an embodiment, the determining the frequency noise power spectral density of the laser under test by using the fourth phase difference data and the fifth phase difference data includes: performing multiple cross-power spectrum calculations by using the fourth phase difference data and the fifth phase difference data; averaging cross power spectra obtained from the multiple cross-power spectrum calculations to obtain a phase noise power spectral density of the laser under test; and determining the frequency noise power spectral density of the laser under test by using the phase noise power spectral density.

In an embodiment, the determining the frequency noise power spectral density of the laser under test based on the fourth phase difference data includes: performing Fourier transform on the fourth phase difference data to obtain a phase noise power spectral density of the laser under test; and determining the frequency noise power spectral density of the laser under test by using the phase noise power spectral density.

In an embodiment, the determining a laser linewidth of the laser under test based on the frequency noise power spectral density includes: performing weighted integration on the frequency noise power spectral density by using a β-separation line method, a direct integration method, or a segmented integration method to determine the laser linewidth of the laser under test.

According to a second aspect of the present disclosure, an apparatus for measuring a laser linewidth based on digital decoherence is provided. The apparatus includes: a processing module, a decoherence module, and a determination module.

The processing module is configured to acquire a first delayed beam and a first reference beam from a laser under test.

The decoherence module is configured to perform digital decoherence at least based on the first delayed beam and the first reference beam to determine a frequency noise power spectral density of the laser under test.

The determination module is configured to determine the laser linewidth of the laser under test based on the frequency noise power spectral density.

A method and an apparatus for measuring a laser linewidth based on digital decoherence are provided according to the above embodiments of the present disclosure. The method includes: acquiring a first delayed beam and a first reference beam from a laser under test; performing digital decoherence at least based on the first delayed beam and the first reference beam to determine a frequency noise power spectral density of the laser under test; and determining the laser linewidth of the laser under test based on the frequency noise power spectral density.

### BRIEF DESCRIPTION OF THE DRAWINGS

To clearly illustrate the technical solutions in the embodiments of the present disclosure or in the related technology, the drawings used in the description of the embodiments or the related technology are briefly described hereinafter. Apparently, the drawings in the following description are only some of the embodiments of the present disclosure, and based on these drawings, other drawings may be obtained by those skilled in the art without any creative effort.

FIG. 1 is a principle architectural diagram of acquiring a power spectral density based on digital decoherence according to an embodiment of the present disclosure;

FIG. 2 is a flowchart of a method for measuring a laser linewidth based on digital decoherence according to an embodiment of the present disclosure;

FIG. 3 is a flowchart of a first method for obtaining a frequency noise power spectral density according to an embodiment of the present disclosure;

FIG. 4 is a flowchart of a second method for obtaining a frequency noise power spectral density according to an embodiment of the present disclosure;

FIG. 5 is a flowchart of performing digital decoherence on first phase difference data to obtain fourth phase difference data according to an embodiment of the present disclosure;

FIG. 6 is a schematic structural diagram of a three-cornered hat system according to an embodiment of the present disclosure; and

FIG. 7 is a structural block diagram of an apparatus for measuring a laser linewidth based on digital decoherence according to an embodiment of the present disclosure.

### DETAILED DESCRIPTION

The technical solutions according to the embodiments of the present disclosure are described clearly and completely as follows in conjunction with the drawings in the embodiments of the present disclosure. Apparently, the described embodiments are only some of the embodiments of the present disclosure, rather than all of the embodiments. All other embodiments obtained by those skilled in the art based on the embodiments of the present disclosure without any creative effort fall within the protection scope of the present disclosure.

In the present disclosure, the terms “include”, “comprise” or any other variants thereof are intended to be non-exclusive. Therefore, a process, method, article or device including a series of elements includes not only these elements but also other elements that are not clearly enumerated, or further includes elements inherent in the process, method, article or device. Unless expressively limited otherwise, a process, method, article or device limited by “comprising/including a(n) . . . ” does not exclude existence of another identical element in such process, method, article or device.

The phase noise and linewidth of a laser are key parameters for evaluating the frequency stability and phase noise characteristics of the laser, which are of great importance in fields such as high-precision laser measurement, optical communication, and quantum technology. The phase noise refers to fluctuations in an output phase of the laser, and is typically characterized by a power spectral density (including a phase noise power spectral density and a frequency noise power spectral density) in the frequency domain. The phase noise reflects short-term random variations in the phase and frequency of the laser.

The linewidth is a parameter that describes an output spectral width of the laser, and is closely related to the phase noise of the laser. The laser with a narrow linewidth provides high frequency stability. High-precision measurements of the phase noise and the linewidth are crucial for evaluating the quality of the laser, and are widely applied in optical frequency atomic clocks, LiDAR, and precision instruments.

Conventional methods for measuring the phase noise and the linewidth of the laser primarily include a direct spectral analysis method, a heterodyne beat method, and a delayed self-heterodyne method. These conventional methods are briefly described below.

In the direct spectral analysis method, the linewidth is measured by directly detecting a spectrum of a laser output signal. Specifically, a laser signal outputted by the laser is sent to a spectrum analyzer which displays frequency distribution of the laser signal. The linewidth refers to a width of the power distribution in the spectrum, and is typically represented by a 3-dB linewidth (that is, the full width at half maximum (FWHM)) of a laser frequency. The direct spectral analysis method can be used to acquire a spectral profile of the laser, and is commonly used to evaluate lasers with relatively large linewidths.

The heterodyne beat method is typically used to evaluate lasers with narrow linewidths. Specifically, an interference measurement is performed on a laser beam under test and a reference laser beam with a similar center wavelength and a comparable or lower noise level to the laser beam under test, to obtain phase difference data or a frequency offset. The principle is that the interference measurement is performed on two laser signals with similar center wavelengths to generate a heterodyne beat signal with a low frequency, and a frequency of the heterodyne beat signal is equal to a difference between frequencies of the two laser signals. By detecting and analyzing phase fluctuation of the heterodyne beat signal, the phase noise of the laser beam under test is obtained, and the linewidth of the laser beam under test is further obtained. When the noise level of the reference laser beam is comparable to that of the laser beam under test, a phase noise spectrum of the heterodyne beat signal is twice that of the laser beam under test. When the noise level of the reference laser beam is lower than that of the laser beam under test, the phase noise spectrum of the heterodyne beat signal is identical to that of the laser beam under test. The heterodyne beat method features a relatively simple structure, and is suitable for measuring lasers with extremely narrow linewidths.

The delayed self-heterodyne method is another commonly used method for measuring the phase noise spectrum of a laser beam. While its principle is analogous to the principle of the heterodyne beat method, it does not require an additional auxiliary laser source. In the delayed self-heterodyne method, the laser beam is split into two beams via an optical coupler. One of the two beams is transmitted through an optical fiber link to introduce a delay exceeding the coherence length, and thus serves as a reference laser beam which is non-coherent with an original laser beam. The interference measurement is performed on the delayed beam and the original laser beam to obtain a heterodyne beat signal. By detecting and analyzing the phase fluctuation of the heterodyne beat signal, the phase noise of the laser beam under test is obtained, and the linewidth of the laser beam under test is further obtained. In this case, the noise level of the reference laser beam is comparable to that of the laser beam under test, and the phase noise spectrum of the heterodyne beat signal is twice that of the laser beam under test. The delayed self-heterodyne method reduces system complexity by obviating the need for an auxiliary laser source, and is widely applied in evaluating laser sources with linewidths at the kHz level and above.

It is found that the direct spectral analysis method exhibits certain limitations in measuring lasers with narrow linewidths. Due to limited frequency resolution of the spectrum analyzer, the linewidth of the laser cannot be accurately measured, particularly for lasers with extremely small frequency fluctuations. Therefore, for the lasers with narrow linewidths, the heterodyne beat method or the delayed self-heterodyne method is generally employed.

When measuring the laser by using the heterodyne beat method, one or more additional reference laser is often required. To achieve the interference measurement between the reference laser and the laser under test, the reference laser and the laser under test with the same center wavelength are required, and the noise level of the reference laser is required to be comparable to or lower than that of the laser under test. Furthermore, due to inherent frequency drift of a laser, it is difficult to perform long-duration interference measurements by using the heterodyne beat method. These factors limit the application of the heterodyne beat method in the evaluation of lasers with narrow linewidths.

In the delayed self-heterodyne method, a delayed beam of the laser serves as the reference laser beam, thus avoiding the limitations of the heterodyne beat method. However, when measuring lasers with Hz-level linewidths, a theoretically required length of a delay fiber reaches on the order of 10⁵ kilometers, which is a huge challenge for the implementation of a physical system. Additionally, the delay fiber introduces substantial environmental noise, which limits the measurement accuracy of the delayed self-heterodyne method.

In summary, the issues in conventional methods for measuring the phase noise and the linewidth of the laser can be mainly divided into two categories. One category involves excessively high requirements for the reference laser (in the heterodyne beat method), resulting in limited flexibility and applicability of the method. The other category involves a complex physical system, insufficient measurement accuracy, and susceptibility to noise interference (in the delayed self-heterodyne method), making the method unsuitable for the lasers with narrow linewidths at the Hz level.

To address the above issues, a method and an apparatus for measuring a laser linewidth based on digital decoherence are provided according to embodiments of the present disclosure. According to the present disclosure, a frequency noise power spectral density used for determining the laser linewidth is determined based on digital decoherence, a center wavelength of a laser under test is not required to match that of an auxiliary laser, and a complex physical optical fiber link is not required to prevent introducing substantial environmental noise, thereby improving the flexibility, applicability, and accuracy of laser linewidth measurement.

That is, in this solution, a linewidth level and a center wavelength of the reference laser are not required to be consistent with those of the laser under test, and a complex physical system composed of ultra-long optical fiber links is not required. This solution enables long-duration measurement of the laser linewidth while improving the flexibility, applicability, and accuracy of laser linewidth measurement.

It should be noted that the fundamental concept of digital decoherence employed in this solution is described as follows. By using a digital delay instead of a physical delay of the optical fiber link, multiplication of the physical delay is achieved through signal processing techniques based on delayed self-heterodyne detection with a short optical fiber link, ultimately obtaining comparative measurement information of two incoherent light sources.

In conventional delayed self-heterodyne measurements, an optical fiber link that is longer than a coherence length of the laser is required to ensure that the delayed beam and the reference beam are incoherent with each other. Thus, evaluation of an Hz-level laser theoretically requires an optical fiber link with a length on the order of 10⁵ kilometers, which not only makes the physical system unfeasible but also introduces substantial environmental noise. In contrast, the digital decoherence can be used in this solution to achieve multiplication of the physical delay by using the digital delay based on a short-delay optical fiber.

To facilitate understanding this solution in the following descriptions, the basic principle of digital decoherence used in this solution is briefly introduced herein (taking a laser under test as an example).

It should be noted that a delayed beam and a reference beam are acquired from the laser under test.

In the first step, a delayed self-heterodyne interference measurement is performed on the laser under test, and a delay of an optical fiber link is determined as τ₀ (that is, a specified delay mentioned subsequently, which is less than a coherence time of the laser under test). Specifically, by using a short-delay self-heterodyne interference system, an interference signal between the delayed beam and the reference beam is measured at a photodetector. An interference measurement result (that is, the measured interference signal) is input to radio frequency devices such as a low-noise radio-frequency power amplifier (LNA) and a filter, and then is subjected to IQ demodulation, to output initial phase difference data Δφ₀₁(t) between the delayed beam and the reference beam. Here, IQ represents in-phase and quadrature, and the initial phase difference data Δφ₀₁(t) is expressed by equation (1).

Δφ₀₁(t)=φ(t)−φ(t−τ₀) (1)

In equation (1), φ(t) represents a phase fluctuation of a laser with time, that is, a phase fluctuation of the reference beam with time; t is an independent variable representing time; and φ(t−τ₀) represents a phase fluctuation of the delayed beam with time. The delayed beam has a delay of τ₀ compared with the reference beam.

In the second step, the initial phase difference data Δφᵢ(t) is delayed by the specified delay (that is, the delay τ₀) to form new phase difference data Δφ₁₂(t)=φ(t−τ₀)−φ(t−2τ₀); and the new phase difference data Δφ₁₂(t)=φ(t−τ₀)−φ(t−2τ₀) is compared with the initial phase difference data Δφ₀₁(t) (the comparison process can be referred to as comparative measurement), to obtain output phase difference data Δφ₀₂(t) corresponding to a delay of 2τ₀. That is, the output phase difference data Δφ₀₂(t) features two specified delays.

It should be noted that, as seen from the initial phase difference data and the new phase difference data formed in the second step, Δφ₀₁(t) and Δφ₁₂(t) share a common component φ(t−τ₀). Thus, by comparing Δφ₀₁(t) with Δφ₁₂(t), a common phase noise term φ(t−τ₀) can be removed, to obtain the output phase difference data Δφ₀₂(t) corresponding to the delay of 2τ₀. The output phase difference data Δφ₀₂(t) is expressed by equation (2) below.

Δφ₀₂(t)=Δφ₀₁(t)+Δφ₂(t)

=φ(t)−φ(t−τ₀)+φ(t−τ₀)−φ(t−2τ₀)

=φ(t)−(φ(t−2τ₀) (2)

In the third step, the operation described in the second step is performed, and is repeated for each step from the third step to the m-th step.

For example, i represents a sequence number of a step. In the i-th step, phase difference data Δφ₍ᵢ₋₂₎₍ᵢ₋₁₎(t)=φ[t−(i−2)τ₀]−φ[t−(i−1)τ₀](in the third step, that is, when i=3, the phase difference data is Δφ₍₃₋₂₎₍₃₋₁₎(t)=(t−τ₀)−φ(t−2τ₀)) is delayed by the specified delay (that is, the delay of τ₀) to form new phase difference data Δφ₍ᵢ₋₁₎ᵢ(t)=φ[t−(i−1)τ₀]−φ(t−iτ₀) (in the third step, that is, when i=3, the new phase difference data is Δφ₂₃(t)=φ(t−2τ₀)−φ(t−3τ₀)).

It should be noted that output phase difference data obtained in the (i−1)th step (that is, the previous step of the i-th step) is Δφ₀₍ᵢ₋₁₎(t)=φ(t)−φ[t−(i−1)τ₀](when i=3, the output phase difference data is Δφ₀₂(t)=φ(t)−φ(t−2τ₀).

The new phase difference data Δφ₍ᵢ₋₁₎ᵢ(t) is compared with the output phase difference data Δφ₀₍ᵢ₋₁₎(t) obtained in the (i−1)th step. It can be seen that Δφ₀₍ᵢ₋₁₎(t) and Δφ₍ᵢ₋₁₎ᵢ(t) share a common component φ[t−(i−1)τ₀], and thus the common phase noise term φ[t−(i−1)τ₀] can be removed to obtain output phase difference data Δφ₀ᵢ(t) corresponding to a delay of iτ₀. The output phase difference data Δφ₀ᵢ(t) corresponding to the delay of iτ₀ is expressed by equation (3) below.

Δφ₀ᵢ(t)=Δφ₀₍ᵢ₋₁₎(t)+Δφ₍ᵢ₋₁₎ᵢ(t)=φ(t)−φ(t−iτ₀) (3)

Through the above steps, a physical delay caused by a short optical fiber link can be accurately multiplied through a digital system. By executing the above steps until the m-th step (until i=m and the m-th step is completed), the delay of the output phase difference data is extended from τ₀ to mτ₀.

It should be noted that the coherence time of the laser is determined by properties of the laser. In a case that mτ₀ is greater than the coherence time of the laser under test, digital decoherence can be achieved, and a comparative measurement result between the phase fluctuation (φ(t)) of the laser under test and a phase fluctuation φ(t−mτ₀) of a beam obtained by delaying beyond the coherence time can be obtained.

For example, when the laser under test is an Hz-level laser, mτ₀>1 s is required to achieve digital decoherence; and when the laser under test is a sub-Hz-level laser, mτ₀>10 s is required to achieve digital decoherence.

Further, Fast Fourier transform (FFT) is performed on the output phase difference data to obtain a power spectral density of phase difference data, based on which a phase-noise power spectral density and a frequency-noise power spectral density can be derived. The power spectral density of the phase difference data is expressed by equation (4).

S_{Δφ}(f)=S_{φ(t)}(f)+S_{φ(t+mτ}_{₀}₎(f)+S_{φ(t)φ(t+mτ}_{₀}₎(f) (4)

In equation (4), S_{Δφ}(f) represents the power spectral density of the phase difference data with a frequency f as an independent variable; S_{φ(t)}(f) represents a phase noise power spectral density of the reference beam; S_{φ(t+mτ}_{₀}₎(f) represents a phase noise power spectral density of the delayed beam with a delay of mτ₀; and S_{φ(t)φ(t+mτ}_{₀}₎(f) represents a cross power spectrum of the reference beam and the delayed beam.

Since the reference beam and the delayed beam originate from the same laser, S_{φ(t)}(f)=S_{φ(t+mτ}_{₀}₎(f)=S_{φ}(f) is met, where S_{φ}(f) represents a phase noise power spectral density of the laser under test. Since the delay time exceeds the coherence time of the laser under test, the reference beam and the delayed beam are not coherent with each other, meaning that the cross power spectrum exhibits random fluctuations that can be neglected over long-duration measurements. Therefore, S_{Δφ}(f)=2S_{φ}(f).

Based on the power spectral density of the phase difference data, the phase noise power spectral density of the laser under test is solved. Further, a frequency noise power spectral density Sᵥ(f) of the laser under test is derived based on Sᵥ(f)=f²S_{φ}(f), and the laser linewidth is calculated by using a β-separation line method.

In practice, due to a large amount of data of the power spectral density in a full frequency domain, Fourier transform is typically performed segmentally through filtering and down-sampling, to obtain power spectral densities for a high-frequency band, a mid-frequency band, and a low-frequency band respectively.

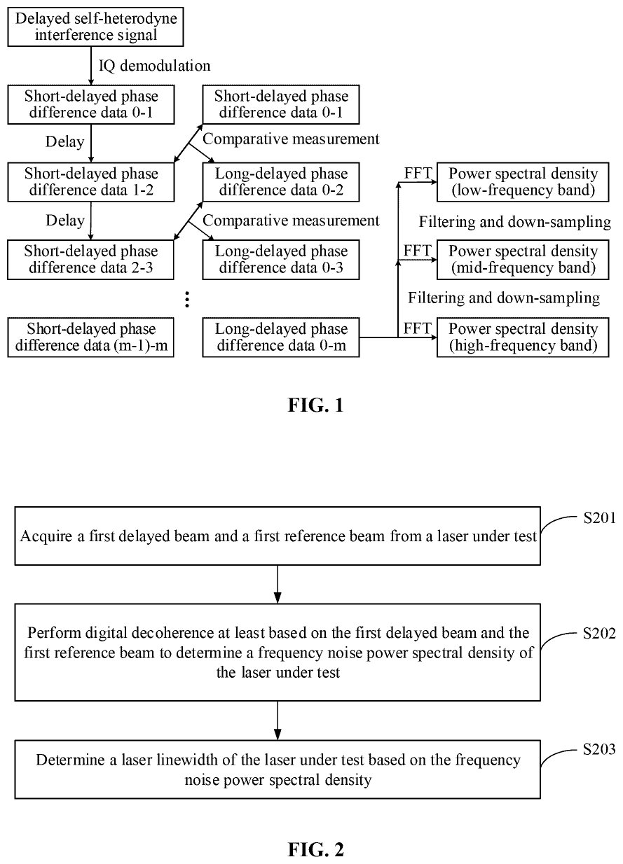

In summary, the principle of acquiring a power spectral density based on digital decoherence is illustrated in FIG. 1. In FIG. 1, the “Delayed self-heterodyne interference signal” is the interference signal of the delayed beam and the reference beam; the “Short-delayed phase difference data 0-1” is the initial phase difference data Δφ₀₁(t); the “Short-delayed phase difference data 1-2” is the new phase difference data Δφ₁₂(t) obtained by delaying Δφ₀₁(t) by τ₀; the “Short-delayed phase difference data 2-3” is the new phase difference data Δφ₂₃(t) obtained by delaying Δφ₁₂(t) by τ₀, and the like.

In FIG. 1, the “Long-delayed phase difference data 0-2” is the output phase difference data Δφ₀₂(t); the “Long-delayed phase difference data 0-3” is the output phase difference data Δφ₀₃(t), and the like. The Fourier transform is performed segmentally through filtering and down-sampling, to obtain the power spectral densities for the high-frequency band, the mid-frequency band, and the low-frequency band respectively.

Hereinabove, the principle of acquiring the power spectral density based on digital decoherence is described.

It should be noted that fluctuations in a laser output frequency is the frequency noise of the laser, and a frequency domain of the fluctuations is the frequency noise power spectral density. The phase noise and the frequency noise of the laser can be measured through different methods, and can be converted to each other.

According to the present disclosure, the laser linewidth is measured based on the above-described principle of acquiring the power spectral density using digital decoherence. Reference is made to FIG. 2, which is a flowchart of a method for measuring a laser linewidth based on digital decoherence according to an embodiment of the present disclosure. The method in FIG. 2 includes steps S201 to S203.

In step S201, a first delayed beam and a first reference beam are acquired from a laser under test.

In a specific implementation of step S201, beams emitted by the laser under test are split into two beams. One is a delayed beam and the other is a reference beam. The delayed beam acquired from the laser under test is referred to as the first delayed beam, and the reference beam acquired from the laser under test is referred to as the first reference beam.

In step S202, digital decoherence is performed at least based on the first delayed beam and the first reference beam to determine a frequency noise power spectral density of the laser under test.

In a specific implementation of step S202, digital decoherence is performed at least based on the first delayed beam and the first reference beam to determine the frequency noise power spectral density of the laser under test.

It should be noted that two methods for obtaining the frequency noise power spectral density are provided according to this solution, which are referred to as a first method for obtaining the frequency noise power spectral density and a second method for obtaining the frequency noise power spectral density.

In the first method for obtaining the frequency noise power spectral density, an auxiliary laser (also referred to as a reference laser) is required to be activated. In the second method for obtaining the frequency noise power spectral density, an auxiliary laser is not required to be activated.

In practice, the first method for obtaining the frequency noise power spectral density or the second method for obtaining the frequency noise power spectral density can be selected based on an actual situation.

For example, when measuring the laser under test with a noise level higher than that of the test environment, the auxiliary laser is activated and the first method for obtaining the frequency noise power spectral density is used to determine the frequency noise power spectral density of the laser under test.

For another example, when measuring the laser under test with a noise level lower than that of the test environment, the auxiliary laser is not activated and the second method for obtaining the frequency noise power spectral density is used to determine the frequency noise power spectral density of the laser under test.

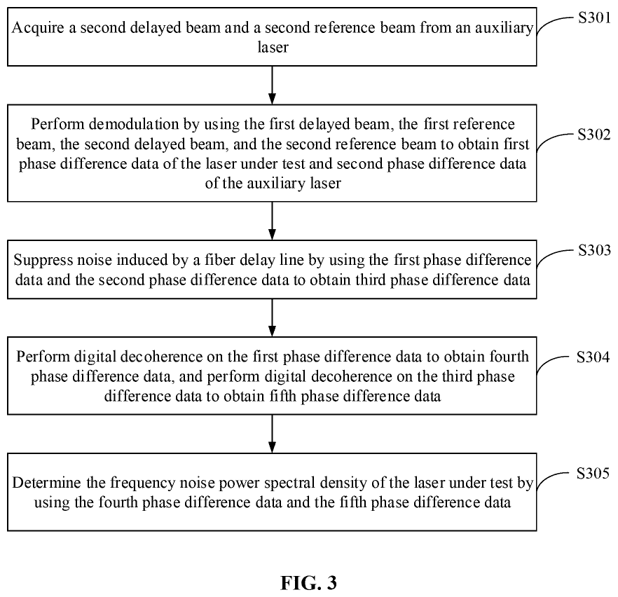

The implementation process of the first method for obtaining the frequency noise power spectral density is explained in detail in subsequent embodiments shown in FIG. 3.

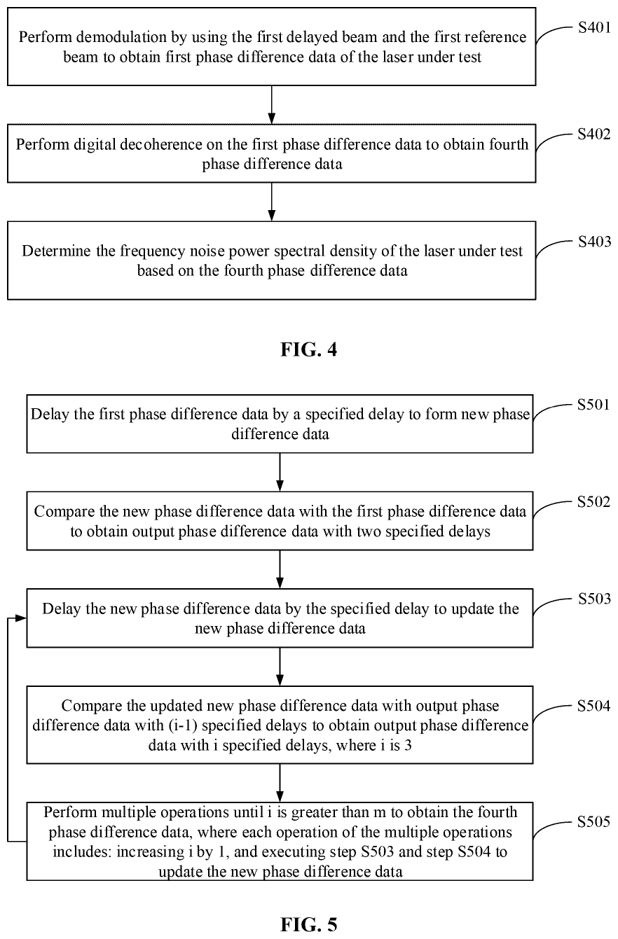

The implementation process of the second method for obtaining the frequency noise power spectral density is explained in detail in subsequent embodiments shown in FIG. 4.

In step S203, the laser linewidth of the laser under test is determined based on the frequency noise power spectral density.

In a specific implementation of step S203, after the frequency noise power spectral density of the laser under test is obtained, weighted integration is performed on the frequency noise power spectral density by using a β-separation line method, a direct integration method, or a segmented integration method to determine the laser linewidth of the laser under test.

In an embodiment, weighted integration is performed on the frequency noise power spectral density of the laser under test, and thus the laser linewidth of the laser under test is determined. The weighted integration may be performed by using the β-separation line method, the direct integration method, or the segmented integration method.

In the embodiments of the present disclosure, the frequency noise power spectral density used for determining the laser linewidth is determined using digital decoherence, a center wavelength of the laser under test is not required to match that of the auxiliary laser, and a complex physical optical fiber link is not required to prevent introducing substantial environmental noise, thereby improving the flexibility, applicability, and accuracy of laser linewidth measurement.

For the first method for obtaining the frequency noise power spectral density involved in step S202 of FIG. 2 in the above-described embodiments of the present disclosure, reference is made to FIG. 3, which is a flowchart of a first method for obtaining a frequency noise power spectral density according to an embodiment of the present disclosure. The method in FIG. 3 includes steps S301 to S305.

In step S301, a second delayed beam and a second reference beam are acquired from an auxiliary laser.

In a specific implementation of step S301, when measuring the laser under test with the noise level higher than that of the test environment, the auxiliary laser is activated, and beams emitted by the auxiliary laser are split into two beams. One is a delayed beam and the other is a reference beam. The delayed beam acquired from the auxiliary laser is referred to as the second delayed beam, and the reference beam acquired from the auxiliary laser is referred to as the second reference beam.

In step S302, demodulation is performed by using the first delayed beam, the first reference beam, the second delayed beam, and the second reference beam to obtain first phase difference data of the laser under test and second phase difference data of the auxiliary laser.

In a specific implementation of step S302, the first delayed beam and the second delayed beam are combined, and a combination of the first delayed beam and the second delayed beam is transmitted to a fiber delay line to obtain a delayed beam, and then frequency shifting is performed on the delayed beam to obtain a third delayed beam.

The third delayed beam and the first reference beam are combined, and an interference measurement is performed on a combination of the third delayed beam and the first reference beam to obtain a first interference signal. The third delayed beam and the second reference beam are combined, and an interference measurement is performed on a combination of the third delayed beam and the second reference beam to obtain a second interference signal.

The first interference signal is demodulated to obtain the first phase difference data, and the second interference signal is demodulated to obtain the second phase difference data.

In an embodiment, the first delayed beam acquired from the laser under test and the second delayed beam acquired from the auxiliary laser are combined through an optical fiber coupler, and a combination of the first delayed beam and the second delayed beam is transmitted to the fiber delay line to obtain a delayed beam. Then, frequency shifting is performed on the delayed beam through an acousto-optic modulator to obtain the third delayed beam.

The third delayed beam is split into two beams. One of the two beams is combined with the first reference beam, and the other beam is combined with the second reference beam. Each of the two combinations of beams is input to an optical filter, and an interference measurement is performed on each of the two combinations of beams at a photodetector. A power of an interference signal obtained from the interference measurement is amplified by using a low-noise amplifier, and excess noise is filtered out by using a filter. Finally, by using a high-speed data acquisition card, the first interference signal and the second interference signal are acquired.

Digital IQ demodulation is performed on the acquired first interference signal to obtain the first phase difference data, and digital IQ demodulation is performed on the acquired second interference signal to obtain the second phase difference data.

It should be noted that a frequency deviation between the delayed beam and the reference beam (for example, the third delayed beam and the first reference beam) involved in the interference measurement exists. The acousto-optic modulator functions to shift a frequency of a beam, which results in the frequency deviation between the delayed beam and the reference beam.

A subsequent interference measurement process by using the photodetector is referred to as a heterodyne interference measurement.

In some embodiments, the first phase difference data and the second phase difference data obtained above each exhibits a specified delay (that is, τ₀). In a case of using the first method for obtaining the frequency noise power spectral density, the first phase difference data (denoted as x_{T}(t)) is expressed by equation (5), and the second phase difference data (denoted as x_{R}(t)) is expressed by equation (6).

$${X}_{T} ( t ) = [ {φ}_{T} ( t ) - {φ}_{T} ( t - {τ}_{0} ) ] + 2 π \frac{n l ( t )}{{λ}_{T}} \qquad ( 5 )$$

$${X}_{R} ( t ) = [ {φ}_{R} ( t ) - {φ}_{R} ( t - {τ}_{0} ) ] + 2 π \frac{n l ( t )}{{λ}_{R}} \qquad ( 6 )$$

In equations (5) and (6), x_{T}(t) represents the first phase difference data (that is, a delayed self-heterodyne interference result of the laser under test), x_{R}(t) represents the second phase difference data (that is, a delayed self-heterodyne interference result of the auxiliary laser),

$$2 π \frac{n l ( t )}{{λ}_{T}} and 2 π \frac{n l ( t )}{{λ}_{R}}$$

represent link noises introduced by fluctuations of the environment in which the optical fiber link is located, λ_{R} represents a wavelength of the auxiliary laser, λ_{T} represents a wavelength of the laser under test, n represents a refractive index of the optical fiber, and l(t) represents the variation of a length of the optical fiber link with time.

It should be noted that the third delayed beam includes two components, one component is derived from delaying the first delayed beam, and the other component is derived from delaying the second delayed beam. When performing the interference measurement between the third delayed beam and the first reference beam, the two components of the third delayed beam are interfered with the first reference beam.

Other interference results are filtered out by one radio frequency filter, and only the result of the interference measurement between the first reference beam and a beam in the third delayed beam which is obtained by delaying the first delayed beam is retained.

Similarly, other interference results are filtered out by another radio frequency filter, and only the result of the interference measurement between the second reference beam and a beam in the third delayed beam which is obtained by delaying the second delayed beam is retained.

In equations (5) and (6), φ_{T}(t) represents a phase fluctuation of the laser under test with time, that is, a phase fluctuation of the first reference beam with time; φ_{T}(t−τ₀) represents a phase fluctuation of a component of the third delayed beam corresponding to the first delayed beam to be combined with the first reference beam with time; φ_{R}(t) represents a phase fluctuation of the auxiliary laser with time, that is, a phase fluctuation of the second reference beam with time; and φ_{R}(t−τ₀) represents a phase fluctuation of a component of the third delayed beam corresponding to the second delayed beam to be combined with the second reference beam with time.

It should be noted that for a laser beam, a magnitude of a sensed noise in the optical fiber link is inversely proportional to its wavelength. Since laser beams from both the auxiliary laser and the laser under test enter the same optical fiber link, and the sensed noise in the optical fiber link is directly proportional to the fluctuation l(t) of the length of the optical fiber link with time, waveform shapes of the noises sensed by the auxiliary laser and the laser under test are identical and the magnitudes of the noises are inversely proportional to the wavelengths of the laser beam.

In step S303, noise induced by a fiber delay line is suppressed by using the first phase difference data and the second phase difference data to obtain third phase difference data.

In a specific implementation of step S303, the noise induced by the fiber delay line is suppressed by using the first phase difference data and the second phase difference data to obtain the third phase difference data X_{T-R}(t).

In an embodiment, in the above process of obtaining the first phase difference data and the second phase difference data, the phase noise of the laser under test and the phase noise of the auxiliary laser are respectively coupled with the noise introduced by the optical fiber link. By effectively suppressing the noise induced by the fiber delay line, a measurement result (that is, the third phase difference data) containing the phase noise of the laser under test and the auxiliary laser is obtained. The third phase difference data X_{T-R}(t) is expressed by equation (7).

x_{T-R}(t)=x_{T}(t)−λ_{R}×x_{R}(t)/λ_{T}

=[φ_{T}(t)−φ_{T}(t−τ₀)]−λ_{R}×[φφ_{R}(t)−φ_{R}(t−τ₀)]λ_{T} (7)

According to equation (7), it can be seen that the third phase difference data exhibits the specified delay (that is, τ₀).

In step S304, digital decoherence is performed on the first phase difference data to obtain fourth phase difference data, and digital decoherence is performed on the third phase difference data to obtain fifth phase difference data.

In a specific implementation of step S304, by using the principle of acquiring the power spectral density based on digital decoherence described above, digital decoherence is performed on the first phase difference data x_{T}(t) to obtain the fourth phase difference data (denoted as X_{T}(t)), and digital decoherence is performed on the third phase difference data X_{T-R}(t) to obtain the fifth phase difference data X_{T-R}(t).

It should be noted that when using the first method for obtaining the frequency noise power spectral density, the first phase difference data corresponds to the initial phase difference data in the aforementioned principle of obtaining the power spectral density based on digital decoherence, and the fourth phase difference data corresponds to the output phase difference data obtained in the m-th step (i=m) in the aforementioned principle of obtaining the power spectral density based on digital decoherence.

Similarly, the third phase difference data corresponds to the initial phase difference data in the aforementioned principle of obtaining the power spectral density based on digital decoherence, and the fifth phase difference data corresponds to the output phase difference data obtained in the m-th step (i=m) in the above-described principle of obtaining the power spectral density based on digital decoherence.

When using the first method for obtaining the frequency noise power spectral density, the fourth phase difference data X_{T}(t) is expressed by equation (8), and the fifth phase difference data X_{T-R}(t) is expressed by equation (9).

X_{T}(t)=[φ_{T}(t)−φ_{T}(t−mτ₀)]+N_{fiber}(t) (8)

X_{T-R}(t)=[φ_{T}(t)−φ_{T}(t−mτ₀)]−λ_{R}×[φ_{R}(t)−φ_{R}(t−mτ₀]/λ_{T} (9)

According to equation (8) and equation (9), it can be seen that after digital decoherence is performed, the delay of the phase noise of the laser is extended from τ₀ (the specified delay) to mτ₀ (m specified delays). The noise induced by the fiber delay line is denoted as N_{fiber}(t), which is the result obtained by performing digital decoherence on the link noise

$$2 π \frac{n l ( t )}{{λ}_{T}}$$

introduced by fluctuations of the environment in which the optical fiber link is located in equation (5).

In some embodiments, the fourth phase difference data and the fifth phase difference data each exhibits m specified delays, and a value of the m specified delays is greater than that of the coherence time of the laser under test.

In step S305, the frequency noise power spectral density of the laser under test is determined by using the fourth phase difference data and the fifth phase difference data.

In a specific implementation of step S305, multiple cross-power spectrum calculations are performed by using the fourth phase difference data and the fifth phase difference data, and cross power spectra obtained from the multiple cross-power spectrum calculations are averaged to obtain a phase noise power spectral density of the laser under test. The frequency noise power spectral density of the laser under test is determined by using the phase noise power spectral density.

In an embodiment, both the fourth phase difference data X_{T}(t) and the fifth phase difference data X_{T-R}(t) contain the phase noise of the laser under test. X_{T}(t) and X_{T-R}(t) are obtained through multiple measurements, to calculate the cross power spectra of X_{T}(t) and X_{T-R}(t). By averaging the cross power spectra obtained from multiple cross-power spectrum calculations, a common-mode component in X_{T}(t) and X_{T-R}(t) is extracted, that is, the phase noise power spectral density of the laser under test is extracted.

The specific calculation process of averaging the cross power spectra obtained from the multiple cross-power spectrum calculations is referred to equation (10).

[symbol]

S_{T(T-R)} [symbol] _{K}= [symbol] S_{TT} [symbol] _{K}− [symbol] S_{TR} [symbol] _{K}+ [symbol] S_{Tfiber} [symbol] _{K}− [symbol] S_{Rfiber} [symbol] _{K}

=S_{TT}+O(\sqrt{1/K}) (10)

In equation (10), [symbol] ● [symbol] , represents averaging of K calculations, S_{T(T-R)} represents the cross power spectrum of X_{T}(t) and X_{T-R}(t), S_{TT} represents a cross power spectrum of φ_{T}(t)−φ_{T}(t−mτ₀) and φ_{T}(t)−φ_{T}(t−mτ₀) (that is, the power spectral density of the phase difference data of the laser under test), S_{TR} represents a cross power spectrum of φ_{T}(t)−φ_{T}(t−mτ₀) and k_{T}×[φ_{R}(t)−φ_{R}(t−mτ₀)]k_{R}, S_{Rfiber} represents a cross power spectrum of the noise N^{fiber}(t) induced by the fiber delay line and λ₀×[φ_{R}(t)−φ_{R} (t−mτ₀], S_{Tfiber} represents a cross power spectrum of the noise N_{fiber}(t) induced by the fiber delay line and [φ_{T}(t)−φ_{T}(t−mτ₀)], and O(\sqrt{1/K}) represents a term on the order of \sqrt{1/K} and decreases as K increases.

It should be noted that a cross power spectrum of two identical items is a positive real number, and a cross power spectrum of two different terms is random fluctuations around zero.

According to the descriptions for equation (10), S_{TT} is a positive real number with a stable amplitude, and the magnitude of S_{TT} remains constant through averaging of the multiple calculations.

The cross power spectra except S_{TT} in equation (10) are all random numbers, which may gradually decrease with the increase of a quantity of the multiple calculations with a decrease ratio being \sqrt{1/K} of an original magnitude. Thus, the measurement result after averaging the cross power spectra obtained from the multiple calculations is S_{TT}+O(\sqrt{1/K}), where O(\sqrt{1/K}) decreases as K increases until it is negligible. Therefore, the result obtained by averaging of the multiple calculations is the power spectral density S_{TT} of the phase difference data of the laser under test. That is, the phase noise power spectral density of the laser under test is S_{TT}.

It should be noted that in an actual process of calculating the cross power spectrum, a higher sampling rate indicates a higher maximum frequency of the cross power spectrum. However, an excessively high sampling rate indicates a high requirement on system resources. Thus, fast Fourier transform (FFT) is often performed on the two sets of data X_{T}(t) and X_{T-R}(t) with high sampling rates, and then conjugate multiplication is performed on two FFT results to obtain a cross power spectrum for a high-frequency band. In addition, the original data X_{T}(t) and X_{T-R}(t) are down-sampled, and the same operation is performed to obtain a cross power spectrum for a mid-frequency band, and the like, to continuously obtain a cross power spectrum for a lower frequency band.

After the phase noise power spectral density S_{TT} of the laser under test is obtained, the frequency noise power spectral density Sᵥ(f) of the laser under test is calculated by Sᵥ(f)=f²S_{TT}(f)/2, where f represents a frequency (that is, an independent variable of the power spectral density).

The content in FIG. 3 according to the above embodiments of the present disclosure is the description of the first method for obtaining the frequency noise power spectral density. After the frequency noise power spectral density of the laser under test is determined by using the first method for obtaining the frequency noise power spectral density, weighted integration is performed on the frequency noise power spectral density by using the β-separation line method, the direct integration method, or the segmented integration method, to determine the laser linewidth of the laser under test.

For example, based on the β-separation line method and the frequency noise power spectral density Sᵥ(f), the laser linewidth of the laser under test is determined.

It should be noted that the β-separation line method is a method for calculating the laser linewidth based on the frequency noise power spectral density. A β-line [(8 ln 2)/π²]f is plotted, Sᵥ(f) at a frequency point satisfying Sᵥ(f)>[(8 ln 2)/π²]f is retained, and integration is performed on the retained portion, so that the laser linewidth is calculated by using the frequency noise power spectral density.

For the second method for obtaining the frequency noise power spectral density involved in step S202 of FIG. 2 in the above embodiments of the present disclosure, reference is made to FIG. 4, which is a flowchart of a second method for obtaining the frequency noise power spectral density according to an embodiment of the present disclosure. The method in FIG. 4 includes steps S401 to S403.

In step S401, demodulation is performed by using the first delayed beam and the first reference beam to obtain first phase difference data of the laser under test.

In a specific implementation of step S401, when measuring the laser under test with a noise level lower than the noise level of the test environment, the auxiliary laser is not activated. The first delayed beam is transmitted into the fiber delay line to obtain a delayed beam, and frequency shifting is performed on the delayed beam to obtain a fourth delayed beam. The fourth delayed beam and the first reference beam are combined, and an interference measurement is performed on a combination of the fourth delayed beam and the first reference beam by using a photodetector to obtain a third interference signal. The third interference signal is demodulated to obtain the first phase difference data.

It should be noted that when using the second method for obtaining the frequency noise power spectral density, the first phase difference data corresponds to the initial phase difference data Δφ₀₁(t) in the aforementioned principle of obtaining the power spectral density based on digital decoherence.

In step S402, digital decoherence is performed on the first phase difference data to obtain fourth phase difference data.

In a specific implementation of step S402, digital decoherence is performed on the first phase difference data to obtain the fourth phase difference data. Here, when using the second method for obtaining the frequency noise power spectral density, the fourth phase difference data corresponds to the output phase difference data obtained in the m-th step (i=m) in the aforementioned principle of obtaining the power spectral density based on digital decoherence.

In step S403, the frequency noise power spectral density of the laser under test is determined based on the fourth phase difference data.

In a specific implementation of step S403, after the fourth phase difference data is obtained, Fourier transform is performed on the fourth phase difference data to obtain a phase noise power spectral density of the laser under test. The frequency noise power spectral density of the laser under test is derived from the phase noise power spectral density.

The content in FIG. 4 according to the above embodiments of the present disclosure is the description of the second method for obtaining the frequency noise power spectral density. After the frequency noise power spectral density of the laser under test is determined by using the second method for obtaining the frequency noise power spectral density, weighted integration is performed on the frequency noise power spectral density by using the β-separation line method, the direct integration method, or the segmented integration method to determine the laser linewidth of the laser under test.

For the performing digital decoherence on the first phase difference data to obtain the fourth phase difference data involved in step S304 of FIG. 3 in the above embodiments of the present disclosure, and the performing digital decoherence on the first phase difference data to obtain the fourth phase difference data involved in step S402 of FIG. 4 in the above embodiments of the present disclosure, a method for performing digital decoherence on phase difference data is described with reference to FIG. 5, and the description is made with an example of performing digital decoherence on the first phase difference data.

Reference is made to FIG. 5, which is a flowchart of performing digital decoherence on first phase difference data to obtain fourth phase difference data according to an embodiment of the present disclosure. The method in FIG. 5 includes steps S501 to S505.

In step S501, the first phase difference data is delayed by a specified delay to form new phase difference data.

In a specific implementation of step S501, according to the principle of obtaining the power spectral density based on digital decoherence described above, the first phase difference data serves as the initial phase difference data and is delayed by the specified delay (τ₀) to form the new phase difference data.

In step S502, the new phase difference data is compared with the first phase difference data to obtain output phase difference data with two specified delays.

In a specific implementation of step S502, the new phase difference data is compared with the first phase difference data to obtain the output phase difference data with two specified delays.

In step S503, the new phase difference data is delayed by the specified delay to update the new phase difference data.

In step S504, the updated new phase difference data is compared with output phase difference data with (i−1) specified delays to obtain output phase difference data with i specified delays, where i is 3.

In a specific implementation of step S504, an initial value of i is 3, and the updated new phase difference data is compared with the output phase difference data with (i−1) specified delays to obtain the output phase difference data with i specified delays.

In step S505, multiple operations are performed until i is greater than m to obtain the fourth phase difference data, where each operation of the multiple operations includes: increasing i by 1, and executing step S503 and step S504 to update the updated new phase difference data.

In a specific implementation of step S505, multiple operations are performed until i is greater than m to obtain the fourth phase difference data, and each operation of the multiple operations includes: increasing i by 1 (i is updated to i+1), and executing step S503 and step S504 to update the updated new phase difference data. The fourth phase difference data is output phase difference data with m specified delays.

It should be noted that the updating the updated new phase difference data specifically refers to delaying the updated new phase difference data used before executing step S505 by the specified delay.

That is, when returning to execute step S503, the updated new phase difference data in the previously executed step S504 is delayed again by the specified delay, and then step S504 to be executed currently is executed. This process is repeated until i is greater than m, to obtain the fourth phase difference data.

In other words, when returning to execute step S503, the “new phase difference data” mentioned in the “delaying the new phase difference data by the specified delay” in step S503 refers to the “updated new phase difference data” in the previously executed step S504.

It should be noted that the principle of steps S501 to S505 may be the same as the principle of obtaining the power spectral density based on digital decoherence described above, which is not repeated here.

It should be further noted that the specific implementation of performing digital decoherence on the third phase difference data to obtain the fifth phase difference data may be referred to the content of FIG. 5 above and the principle of obtaining the power spectral density based on digital decoherence described above, which is not repeated here. The obtained fifth phase difference data is output phase difference data with m specified delays.

Hereinabove, the method for measuring a laser linewidth based on digital decoherence is described according to this solution. In practice, when using the first method for obtaining the frequency noise power spectral density, a three-cornered hat system is established to implement the method for measuring a laser linewidth based on digital decoherence.

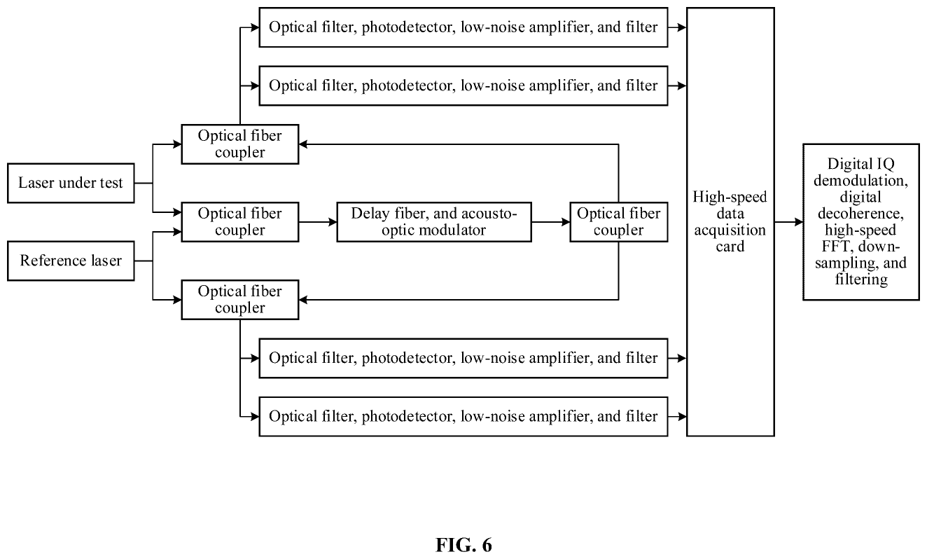

For example, FIG. 6 is a schematic structural diagram of a three-cornered hat system according to an embodiment of the present disclosure. The three-cornered hat system shown in FIG. 6 includes an optical unit, a radio frequency unit, and a high-speed data processing unit.

The optical unit of the three-cornered hat system primarily includes an auxiliary laser, a delay fiber, an acousto-optic modulator, a photodetector, an optical filter (as shown in FIG. 6), and an optical fiber coupler. Delayed self-heterodyne interference measurements for the laser under test and the auxiliary laser can be implemented through the optical unit. A center wavelength of the auxiliary laser is not required to be the same as that of the laser under test, and a laser linewidth of the auxiliary laser is not required to be comparable to that of the laser under test.

The radio frequency unit of the three-cornered hat system includes two parallel sets of low-noise radio-frequency power amplifiers (abbreviated as low-noise amplifiers in FIG. 6) and radio frequency filters (abbreviated as filters in FIG. 6), and a 4-channel high-speed data acquisition card. The amplification, filtering, and high-speed acquisition of two sets of interference signals can be implemented through the radio frequency unit.

It should be noted that when an extremely high requirement for signal-to-noise ratio exists, or the quality of the laser under test is exceptionally high, and the noise of radio frequency devices is required to be suppressed, each set of the two sets of low-noise radio-frequency power amplifiers and radio frequency filters may include two sets of devices. That is, four sets of devices are provided in total. In this case, the noise of radio frequency devices can be suppressed through a specific method.

The high-speed data processing unit of the three-cornered hat system primarily includes a field programmable gate array (FPGA) high-speed processing board and a high-speed data memory. Through the high-speed data processing unit, digital IQ demodulation is performed on sampled signals to obtain the initial phase difference data, and digital decoherence is performed on the initial phase difference data to obtain the output phase difference data (that is, the long-delay phase difference data in FIG. 1). Further, operations such as FFT, filtering, and down-sampling are performed on the output phase difference data to obtain the phase noise power spectral density or the frequency noise power spectral density of the laser, and finally the laser linewidth is calculated. Simultaneously, the high-speed data memory stores valid data such as the phase difference data, the phase noise power spectral density or the frequency noise power spectral density to meet other analysis requirements.

When measuring the laser linewidth by using the three-cornered hat system shown in FIG. 6, the first delayed beam acquired from the laser under test and the second delayed beam acquired from the auxiliary laser are combined by the optical fiber coupler, and are transmitted to the fiber delay line to obtain a delayed beam. Then, frequency shifting is performed on the delayed beam through the acousto-optic modulator to obtain the third delayed beam.

The third delayed beam is split into two beams. These two beams of the third delayed beam are combined with the first reference beam and the second reference beam through optical fiber couplers, respectively. The two combinations of beams are input to optical filters, and then interference measurements are performed on them at photodetectors. Powers of two interference signals obtained from the interference measurements are amplified through low-noise amplifiers, and excess noises are filtered out through filters. Finally, by using the high-speed data acquisition card, the first interference signal and the second interference signal are acquired.

Digital IQ demodulation is performed on the acquired first interference signal and the acquired second interference signal, to obtain the first phase difference data and the second phase difference data. The subsequent process of calculating the laser linewidth of the laser under test based on the first phase difference data and the second phase difference data may refer to relevant contents in FIG. 3 according to the above embodiments of the present disclosure, which is not repeated here.

It should be noted that with the three-cornered hat system according to the embodiments of the present disclosure, a measurement result containing noise contributions of noises from any two of the laser under test, the auxiliary laser, and the optical fiber link can be obtained.

A dual-laser structure shown in FIG. 6 is merely an example of the three-cornered hat system according to the embodiments of the present disclosure. The key feature of the three-cornered hat system lies in three mutually independent units being formed by the laser sources and the optical fiber link. Therefore, similar functions can be achieved by using one laser and two different optical fiber links or three lasers. Various implementations of the three-cornered hat system are not described in detail here.

In summary, based on the above embodiments, the present disclosure has the following beneficial effects.

Firstly, multiplication of the physical delay of the optical fiber link is achieved by using a digital delay. Compared with the conventional delayed self-heterodyne method, a complex physical optical fiber link is not required according to the present disclosure. The delay introduced by a short physical optical fiber link can be increased multiplicatively via digital delay, achieving equivalent decoherence of the laser source and thereby obtaining an accurate power spectral density.

Secondly, one or more additional auxiliary laser which exhibits similar center wavelength to the laser under test and exhibits a linewidth level close to or superior to the laser under test is not required according to the present disclosure. The interference measurement is not directly performed between the laser under test and the auxiliary laser. Instead, the delayed self-heterodyne interference measurement is performed independently, allowing for a wide selection range of the auxiliary laser with almost no restrictions on the center wavelength or linewidth, and enabling long-duration continuous measurements without being affected by inherent frequency drift of the laser.

Thirdly, the three-cornered hat system according to the present disclosure can be implemented by using one reference laser and one delay link, and can be alternatively implemented by using either two delay links or two auxiliary lasers, which provides high flexibility in the implementation of the three-cornered hat system. By using the three-cornered hat system, accurate measurement of a noise spectrum and a linewidth of a narrow-linewidth laser can be achieved.

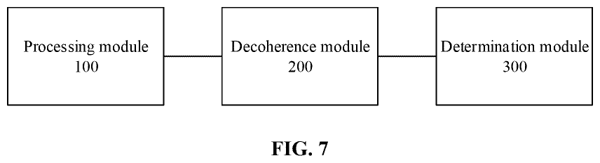

Corresponding to the method for measuring a laser linewidth based on digital decoherence according to the above embodiments of the present disclosure, reference is made to FIG. 7, which is a structural block diagram of an apparatus for measuring a laser linewidth based on digital decoherence according to an embodiment of the present disclosure. The apparatus includes a processing module 100, a decoherence module 200, and a determination module 300.

The processing module 100 is configured to acquire a first delayed beam and a first reference beam from a laser under test.

The decoherence module 200 is configured to perform digital decoherence at least based on the first delayed beam and the first reference beam to determine a frequency noise power spectral density of the laser under test.

The determination module 300 is configured to determine the laser linewidth of the laser under test based on the frequency noise power spectral density.

In some embodiments, the determination module 300 is further configured to perform weighted integration on the frequency noise power spectral density by using a β-separation line method, a direct integration method, or a segmented integration method to determine the laser linewidth of the laser under test.

In the embodiments of the present disclosure, the frequency noise power spectral density used for determining the laser linewidth is determined through digital decoherence, a center wavelength of the laser under test is not required to be the same as that of the auxiliary laser, and a complex physical optical fiber link is not required to avoid introducing substantial environmental noise, thereby improving the flexibility, applicability, and accuracy of laser linewidth measurement.

In an embodiment, in conjunction with contents shown in FIG. 7, the decoherence module 200 includes a splitting sub-module, a first demodulation sub-module, a suppressing sub-module, a first decoherence sub-module, and a first determination sub-module. The implementations of the sub-modules are described as follows.

The splitting sub-module is configured to acquire a second delayed beam and a second reference beam from an auxiliary laser.

The first demodulation sub-module is configured to perform demodulation by using the first delayed beam, the first reference beam, the second delayed beam, and the second reference beam to obtain first phase difference data of the laser under test and second phase difference data of the auxiliary laser.

In some embodiments, the first demodulation sub-module is further configured to: combine the first delayed beam and the second delayed beam, transmit a combination of the first delayed beam and the second delayed beam to a fiber delay line to obtain a delayed beam, and perform frequency shifting on the delayed beam to obtain a third delayed beam; combine the third delayed beam and the first reference beam, perform an interference measurement on a combination of the third delayed beam and the first reference beam to obtain a first interference signal, combine the third delayed beam and the second reference beam, and perform an interference measurement on a combination of the third delayed beam and the second reference beam to obtain a second interference signal; and demodulate the first interference signal to obtain the first phase difference data, and demodulate the second interference signal to obtain the second phase difference data.

The suppressing sub-module is configured to suppress a noise induced by a fiber delay line by using the first phase difference data and the second phase difference data to obtain third phase difference data.

The first decoherence sub-module is configured to perform digital decoherence on the first phase difference data to obtain fourth phase difference data, and perform digital decoherence on the third phase difference data to obtain fifth phase difference data.

The first determination sub-module is configured to determine the frequency noise power spectral density of the laser under test by using the fourth phase difference data and the fifth phase difference data.

In some embodiments, the first determination sub-module is further configured to: perform multiple cross-power spectrum calculations by using the fourth phase difference data and the fifth phase difference data; average cross power spectra obtained from the multiple cross-power spectrum calculations to obtain a phase noise power spectral density of the laser under test; and determine the frequency noise power spectral density of the laser under test by using the phase noise power spectral density.

In an embodiment, in conjunction with the contents shown in FIG. 7, the decoherence module 200 includes a second demodulation sub-module, a second decoherence sub-module, and a second determination sub-module. The implementations of the sub-modules are described as follows.

The second demodulation sub-module is configured to perform demodulation by using the first delayed beam and the first reference beam to obtain first phase difference data of the laser under test.

In some embodiments, the second demodulation sub-module is further configured to: transmit the first delayed beam to a fiber delay line to obtain a delayed beam, and perform frequency shifting on the delayed beam to obtain a fourth delayed beam; combine the fourth delayed beam and the first reference beam, and perform an interference measurement on a combination of the fourth delayed beam and the first reference beam by using a photodetector to obtain a third interference signal; and demodulate the third interference signal to obtain the first phase difference data.

The second decoherence sub-module is configured to perform digital decoherence on the first phase difference data to obtain fourth phase difference data.

The second determination sub-module is configured to determine the frequency noise power spectral density of the laser under test based on the fourth phase difference data.

In some embodiments, the second determination sub-module is further configured to: perform Fourier transform on the fourth phase difference data to obtain a phase noise power spectral density of the laser under test; and determine the frequency noise power spectral density of the laser under test by using the phase noise power spectral density.

In some embodiments, the performing digital decoherence on the first phase difference data to obtain the fourth phase difference data in the processes of the first decoherence sub-module and the second decoherence sub-module includes: delaying the first phase difference data by a specified delay to form new phase difference data; comparing the new phase difference data with the first phase difference data to obtain output phase difference data with two specified delays; delaying the new phase difference data by the specified delay to update the new phase difference data; comparing the updated new phase difference data with output phase difference data with (i−1) specified delays to obtain output phase difference data with i specified delays, where i is 3; and performing multiple operations until i is greater than m to obtain the fourth phase difference data, where each operation of the multiple operations includes: increasing i by 1, delaying the new phase difference data by the specified delay to update the new phase difference data, and comparing the updated new phase difference data with output phase difference data with (i−1) specified delays to obtain output phase difference data with i specified delays, and the fourth phase difference data is output phase difference data with m specified delays.

In summary, a method and an apparatus for measuring a laser linewidth based on digital decoherence are provided according to embodiments of the present disclosure. According to the present disclosure, the frequency noise power spectral density used for determining the laser linewidth is determined through digital decoherence, a center wavelength of the laser under test is not required to be the same as that of the auxiliary laser, and a complex physical optical fiber link is not required to avoid introducing substantial environmental noise, thereby improving the flexibility, applicability, and accuracy of laser linewidth measurement.

The embodiments in this specification are described in a progressive manner. Various embodiments may refer to each other for the same or similar parts, and each embodiment places emphasis on the difference from other embodiments. In particular, the system or system embodiment is basically similar to the method embodiment, and therefore is described relatively briefly. For relevant details, reference can be made to the corresponding description of the method embodiment. The system and system embodiments described above are only schematic, in which the units described as separate components may or may not be physically separated, and the components shown as units may or may not be physical units, that is, the components may be located in one place or distributed at multiple network units. Some or all modules may be selected according to an actual requirement to achieve an objective of a solution of an embodiment. Those skilled in the art can understand and implement the solution without any creative effort.

Those skilled in the art may further realize that the units and algorithm steps of each example described in conjunction with the embodiments disclosed herein can be implemented by electronic hardware, computer software, or a combination of both. To clearly illustrate the interchangeability of hardware and software, the modules and steps of each example are described in general terms of functionality in the above description. Whether these functions are performed in hardware or software depends on specific applications and design constraints of the technical solution. Those skilled in the art may implement the described functionality in various manners for respective specific applications, and such implementations should not be considered to be beyond the scope of the present disclosure.

According to the above description of the disclosed embodiments, those skilled in the art can implement or practice the present disclosure. Various modifications to these embodiments are apparent to those skilled in the art, and the general principles defined herein may be implemented in other embodiments without departing from the scope of the present disclosure. Therefore, the present disclosure is not to be limited to the embodiments illustrated herein, but should be conformed to the widest scope consistent with the principles and novel features disclosed herein.

1. A method for measuring a laser linewidth based on digital decoherence, comprising:
acquiring a first delayed beam and a first reference beam from a laser under test;
performing digital decoherence at least based on the first delayed beam and the first reference beam to determine a frequency noise power spectral density of the laser under test; and
determining the laser linewidth of the laser under test based on the frequency noise power spectral density.

2. The method according to claim 1, wherein the performing digital decoherence at least based on the first delayed beam and the first reference beam to determine a frequency noise power spectral density of the laser under test comprises:
acquiring a second delayed beam and a second reference beam from an auxiliary laser;
performing demodulation by using the first delayed beam, the first reference beam, the second delayed beam, and the second reference beam to obtain first phase difference data of the laser under test and second phase difference data of the auxiliary laser;
suppressing noise induced by a fiber delay line by using the first phase difference data and the second phase difference data to obtain third phase difference data;
performing digital decoherence on the first phase difference data to obtain fourth phase difference data, and performing digital decoherence on the third phase difference data to obtain fifth phase difference data; and
determining the frequency noise power spectral density of the laser under test by using the fourth phase difference data and the fifth phase difference data.

3. The method according to claim 1, wherein the performing digital decoherence at least based on the first delayed beam and the first reference beam to determine a frequency noise power spectral density of the laser under test comprises:
performing demodulation by using the first delayed beam and the first reference beam to obtain first phase difference data of the laser under test;
performing digital decoherence on the first phase difference data to obtain fourth phase difference data; and
determining the frequency noise power spectral density of the laser under test based on the fourth phase difference data.

4. The method according to claim 2, wherein the performing demodulation by using the first delayed beam, the first reference beam, the second delayed beam, and the second reference beam to obtain first phase difference data of the laser under test and second phase difference data of the auxiliary laser comprises:
combining the first delayed beam and the second delayed beam, transmitting a combination of the first delayed beam and the second delayed beam to the fiber delay line to obtain a delayed beam, and performing frequency shifting on the delayed beam to obtain a third delayed beam;
combining the third delayed beam and the first reference beam, performing an interference measurement on a combination of the third delayed beam and the first reference beam to obtain a first interference signal, combining the third delayed beam and the second reference beam, and performing an interference measurement on a combination of the third delayed beam and the second reference beam to obtain a second interference signal; and
demodulating the first interference signal to obtain the first phase difference data, and demodulating the second interference signal to obtain the second phase difference data.

5. The method according to claim 3, wherein the performing demodulation by using the first delayed beam and the first reference beam to obtain first phase difference data of the laser under test comprises:
transmitting the first delayed beam to a fiber delay line to obtain a delayed beam, and performing frequency shifting on the delayed beam to obtain a fourth delayed beam;
combining the fourth delayed beam and the first reference beam, and performing an interference measurement on a combination of the fourth delayed beam and the first reference beam by using a photodetector to obtain a third interference signal; and
demodulating the third interference signal to obtain the first phase difference data.

6. The method according to claim 3, wherein the performing digital decoherence on the first phase difference data to obtain fourth phase difference data comprises:
delaying the first phase difference data by a specified delay to form new phase difference data;
comparing the new phase difference data with the first phase difference data to obtain output phase difference data with two specified delays;
delaying the new phase difference data by the specified delay to update the new phase difference data;
comparing the updated new phase difference data with output phase difference data with (i−1) specified delays to obtain output phase difference data with i specified delays, wherein i is 3; and
performing a plurality of operations until i is greater than m to obtain the fourth phase difference data, wherein each operation of the plurality of operations comprises: increasing i by 1, delaying the new phase difference data by the specified delay to update the new phase difference data, and comparing the updated new phase difference data with output phase difference data with (i−1) specified delays to obtain output phase difference data with i specified delays, and the fourth phase difference data is output phase difference data with m specified delays.

7. The method according to claim 2, wherein the determining the frequency noise power spectral density of the laser under test by using the fourth phase difference data and the fifth phase difference data comprises:
performing a plurality of cross-power spectrum calculations using the fourth phase difference data and the fifth phase difference data;
averaging cross power spectra obtained from the plurality of cross-power spectrum calculations to obtain a phase noise power spectral density of the laser under test; and
determining the frequency noise power spectral density of the laser under test by using the phase noise power spectral density.

8. The method according to claim 3, wherein the determining the frequency noise power spectral density of the laser under test based on the fourth phase difference data comprises:
performing Fourier transform on the fourth phase difference data to obtain a phase noise power spectral density of the laser under test; and
determining the frequency noise power spectral density of the laser under test by using the phase noise power spectral density.

9. The method according to claim 1, wherein the determining the laser linewidth of the laser under test based on the frequency noise power spectral density comprises:
performing weighted integration on the frequency noise power spectral density by using a β-separation line method, a direct integration method, or a segmented integration method to determine the laser linewidth of the laser under test.

10. An apparatus for measuring a laser linewidth based on digital decoherence, comprising:
a processing module, configured to acquire a first delayed beam and a first reference beam from a laser under test;
a decoherence module, configured to perform digital decoherence at least based on the first delayed beam and the first reference beam to determine a frequency noise power spectral density of the laser under test; and
a determination module, configured to determine the laser linewidth of the laser under test based on the frequency noise power spectral density.
